(19) United States
(12) Patent Application Publication
(10) Pub. No.: US 2012/0261541 A1
(43) Pub. Date: Oct. 18, 2012

(54) Angle Adjustable Support Device for Placing and Supporting an Electronic Equipment on a Table

(76) Inventor: Hsiu-Chen Lai, Chang Hua City (TW)

(21) Appl. No.: 13/085,540

(22) Filed: Apr. 13, 2011

(51) Int. Cl. H05K 7/00; F16M 13/00

(52) U.S. Cl. 248/346.5; 248/346.01

(57) ABSTRACT

A support device for a 3C electronic equipment includes a fixed board, a movable board pivotally connected with the fixed board, and an angle adjusting mechanism mounted between the fixed board and the movable board to releasably lock the movable board onto the fixed board. Thus, the movable board is adjusted and inclined relative to the fixed board so that the electronic equipment placed on the movable board is disposed at an inclined state so as to facilitate the user watching the electronic equipment and so as to provided a comfortable sensation to the user when operating the electronic equipment.

### BACKGROUND OF THE INVENTION

1. Field of the Invention

The present invention relates to a support device and, more particularly, to a support device for placing and supporting a 3C electronic equipment, such as a tablet PC, a notebook computer, a PDA, an electronic book and the like.

2. Description of the Related Art

A conventional flat-shaped electronic equipment, such as a tablet PC, a PDA, an electronic book and the like, usually has a smaller volume and is carried easily and conveniently to facilitate a user carrying and operating the flat-shaped electronic equipment. However, when the flat-shaped electronic equipment is placed on a table, the screen of the flat-shaped electronic equipment is parallel with the table and is not disposed at an inclined position so that the user cannot watch and operate the flat-shaped electronic equipment easily and conveniently, thereby causing inconvenience to the user and easily causing an uncomfortable sensation to the user.

### BRIEF SUMMARY OF THE INVENTION

In accordance with the present invention, there is provided a support device, comprising a fixed board, a movable board pivotally connected with the fixed board, and an angle adjusting mechanism mounted between the fixed board and the movable board to releasably lock the movable board onto the fixed board. The fixed board has a side provided with two support seats. The movable board has a side provided with two pivot seats pivotally connected with the two support seats of the fixed board respectively. One of the two pivot seats of the movable board has a periphery provided with a plurality of one-way ratchet teeth. The angle adjusting mechanism includes a limit member pivotally mounted on one of the two support seats of the fixed board and detachably engaging one of the two pivot seats of the movable board to releasably lock one of the two pivot seats of the movable board onto one of the two support seats of the fixed board and to releasably lock the movable board onto the fixed board. The limit member of the angle adjusting mechanism has a first end pivotally connected with one of the two support seats of the fixed board and a second end provided with a locking detent detachably engaging one of the ratchet teeth of the movable board.

The primary objective of the present invention is to provide an angle adjustable support device for placing and supporting an electronic equipment on a table.

According to the primary advantage of the present invention, the movable board is inclined relative to the fixed board so that the electronic equipment placed on the movable board is disposed at an inclined state to facilitate the user watching the electronic equipment and to provided a comfortable sensation to the user when operating the electronic equipment.

According to another advantage of the present invention, the user only needs to pull and move the movable board relative to the fixed board so as to position the movable board onto the fixed board exactly so that the inclined angle of the movable board relative to the fixed board can be adjusted easily and quickly.

According to a further advantage of the present invention, the movable board is extended into the opening of the fixed board so that the support device can be folded to have a smaller volume when not in use to save the space and to facilitate storage and carrying of the support device.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a perspective view of a support device in accordance with the preferred embodiment of the present invention.

FIG. 2 is an exploded perspective view of the support device as shown in FIG. 1.

FIG. 3 is a locally enlarged view of the support device as shown in FIG. 2.

FIG. 4 is a locally enlarged view of the support device as shown in FIG. 2.

FIG. 5 is a locally enlarged view of the support device as shown in FIG. 1.

FIG. 6 is a schematic operational view of the support device as shown in FIG. 1.

FIG. 7 is a locally enlarged side cross-sectional view of the support device as shown in FIG. 6.

FIG. 8 is a schematic operational view of the support device as shown in FIG. 6.

FIG. 9 is a locally enlarged side cross-sectional view of the support device as shown in FIG. 8.

FIG. 10 is a schematic operational view of the support device as shown in FIG. 8.

FIG. 11 is a locally enlarged side cross-sectional view of the support device as shown in FIG. 10.

FIG. 12 is a side view of a support device in accordance with another preferred embodiment of the present invention.

### DETAILED DESCRIPTION OF THE INVENTION

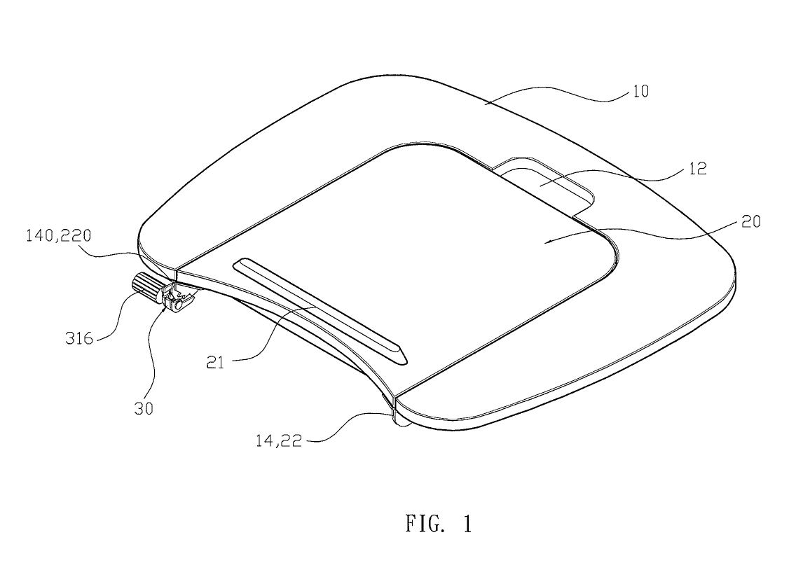

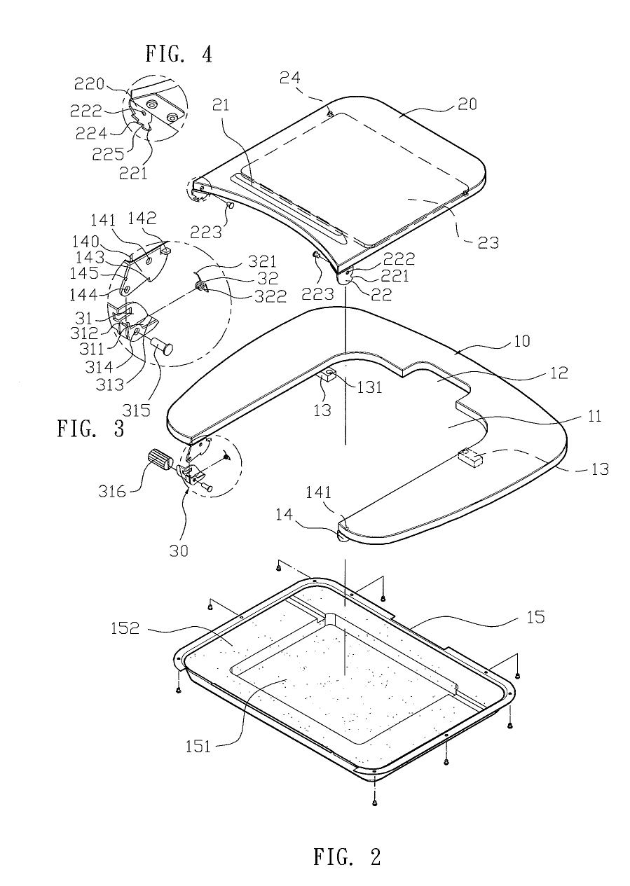

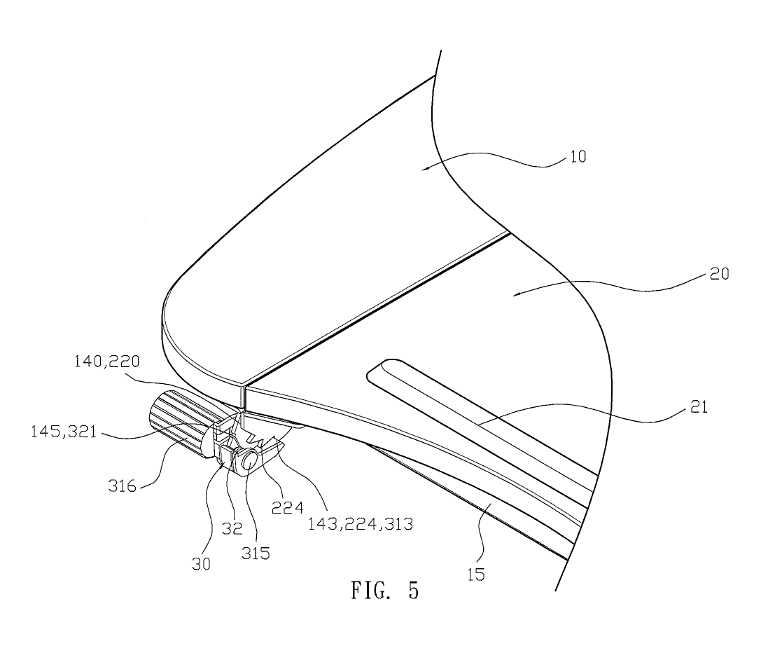

Referring to the drawings and initially to FIGS. 1-7, a support device for a 3C electronic equipment in accordance with the preferred embodiment of the present invention comprises a fixed board 10, a movable board 20 pivotally connected with the fixed board 10, and an angle adjusting mechanism 3 mounted between the fixed board 10 and the movable board 20 to releasably lock the movable board 20 onto the fixed board 10.

The fixed board 10 has a substantially U-shaped profile. The fixed board 10 has a surface provided with an opening 11 to receive the movable board 20. The fixed board 10 has a side provided with two support seats 14 and 140. One of the two support seats 14 and 140 of the fixed board 10 has a periphery provided with an abutting edge 143 and has a side provided with a fixing hole 144. The fixing hole 144 of the fixed board 10 is located beside the abutting edge 143 of the fixed board 10.

The movable board 20 is fully received in the opening 11 of the fixed board 10 and has a side provided with two pivot seats 22 and 220 pivotally connected with the two support seats 14 and 140 of the fixed board 10 respectively. One of the two pivot seats 22 and 220 of the movable board 20 has a periphery provided with a plurality of oneway ratchet teeth 224. The ratchet teeth 224 of the movable board 20 are rotatable and movable relative to the fixed board 10 and the angle adjusting mechanism 3 by rotation of the movable board 20. One of the two pivot seats 22 and 220 of the movable board 20 has a plurality of locking grooves 225 defined between the ratchet teeth 224.

The angle adjusting mechanism 3 includes a limit member 31 pivotally mounted on one of the two support seats 14 and 140 of the fixed board 10 and detachably engaging one of the two pivot seats 22 and 220 of the movable board 20 to releasably lock one of the two pivot seats 22 and 220 of the movable board 20 onto one of the two support seats 14 and 140 of the fixed board 10 and to releasably lock the movable board 20 onto the fixed board 10.

The limit member 31 of the angle adjusting mechanism 3 has a first end pivotally connected with one of the two support seats 14 and 140 of the fixed board 10 and a second end provided with a locking detent 313 detachably engaging one of the ratchet teeth 224 of the movable board 20. The locking detent 313 of the limit member 31 is hooked onto the abutting edge 143 of the fixed board 10 and detachably locked in one of the locking grooves 225 of the movable board 20. The first end of the limit member 31 is pivotally connected with one of the two support seats 14 and 140 of the fixed board 10 by a pivot shaft 315. The first end of the limit member 31 has a side provided with a pivot hole 314 aligning with the fixing hole 144 of the fixed board 10, and the pivot shaft 315 is extended through the pivot hole 314 of the limit member 31 and the fixing hole 144 of the fixed board 10 so that the limit member 31 of the angle adjusting mechanism 3 is pivotally connected with one of the two support seats 14 and 140 of the fixed board 10. Thus, the limit member 31 of the angle adjusting mechanism 3 is pivotable about the pivot shaft 315 and is movable relative to the movable board 20 so that the locking detent 313 of the limit member 31 is movable relative to the ratchet teeth 224 of the movable board 20.

In the preferred embodiment of the present invention, the opening 11 of the fixed board 10 has a periphery provided with a finger slot 12 connected to the movable board 20 to facilitate a user removing the movable board 20 from the opening 11 of the fixed board 10. The fixed board 10 has a periphery provided with two stop blocks 13 each extended into the opening 11 of the fixed board 10 to stop the movable board 20. Each of the two stop blocks 13 of the fixed board 10 has a side provided with an attractive member 131. The attractive member 131 of each of the two stop blocks 13 is a magnet or magnetic stone. The movable board 20 has an inner face provided with a buffering pad 23 received in the opening 11 of the fixed board 10 and has an outer face provided with a transverse support bar 21. The buffering pad 23 of the movable board 20 has a periphery provided with two attachment members 24 each detachably attached to the attractive member 131 of a respective one of the two stop blocks 13. The support device further comprises a receiving casing 15 mounted on the fixed board 10, and a buffering cushion 152 mounted in the receiving casing 15 and provided with a receiving chamber 151 which is connected to the opening 11 of the fixed board 10 to receive an article, such as a tablet PC, a notebook computer, a PDA, an electronic book and the like. The buffering cushion 152 faces the movable board 20.

Each of the two support seats 14 and 140 of the fixed board 10 has a distal end provided with a protruding stop rib 142, and each of the two pivot seats 22 and 220 of the movable board 20 has a rim provided with a protruding limit lug 221 that is movable to abut the stop rib 142 of a respective one of the two support seats 14 and 140 of the fixed board 10 to stop a further movement of the movable board 20 relative to the fixed board 10.

Each of the two pivot seats 22 and 220 of the movable board 20 is pivotally connected with each of the two support seats 14 and 140 of the fixed board 10 by a pivot pin 223. Each of the two support seats 14 and 140 of the fixed board 10 has a mediate portion provided with a fixing bore 141, each of the two pivot seats 22 and 220 of the movable board 20 has a central portion provided with a pivot bore 222, and the pivot pin 223 is in turn extended through the pivot bore 222 of each of the two pivot seats 22 and 220 of the movable board 20 and the fixing bore 141 of each of the two support seats 14 and 140 of the fixed board 10 so that each of the two pivot seats 22 and 220 of the movable board 20 is pivotally connected with each of the two support seats 14 and 140 of the fixed board 10. Thus, the movable board 20 is pivotable about the pivot pin 223 and is movable relative to the fixed board 10.

The angle adjusting mechanism 3 further includes a rotation knob 316 secured on the limit member 31 to drive and pivot the limit member 31 relative to one of the two support seats 14 and 140 of the fixed board 10 and one of the two pivot seats 22 and 220 of the movable board 20, and an elastic member 32 mounted in the limit member 31 and biased between the limit member 31 and one of the two support seats 14 and 140 of the fixed board 10 to force the locking detent 313 of the limit member 31 toward the ratchet teeth 224 of the movable board 20. One of the two support seats 14 and 140 of the fixed board 10 has a rim provided with a retaining recess 145. The retaining recess 145 of the fixed board 10 is located adjacent to the fixing hole 144 of the fixed board 10. The limit member 31 of the angle adjusting mechanism 3 has a side provided with a catch portion 312, and the pivot hole 314 of the limit member 31 is located between the catch portion 312 and the locking detent 313. The limit member 31 of the angle adjusting mechanism 3 has an inner portion provided with a receiving space 311 to receive one of the two support seats 14 and 140 of the fixed board 10 and one of the two pivot seats 22 and 220 of the movable board 20. The receiving space 311 of the limit member 31 is located between the catch portion 312 and the locking detent 313. The elastic member 32 of the angle adjusting mechanism 3 is a torsion spring and has a first end provided with a hooked portion 321 hooked in the retaining recess 145 of the fixed board 10 and a second end provided with a resting portion 322 abutting the catch portion 312 and the locking detent 313. The elastic member 32 of the angle adjusting mechanism 3 is received in the receiving space 311 of the limit member 31 and is rotatably mounted on the pivot shaft 315.

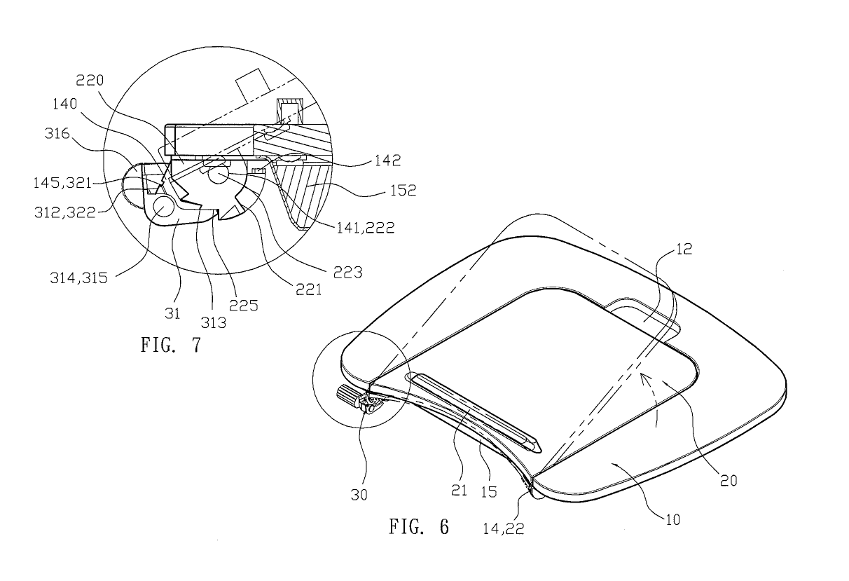

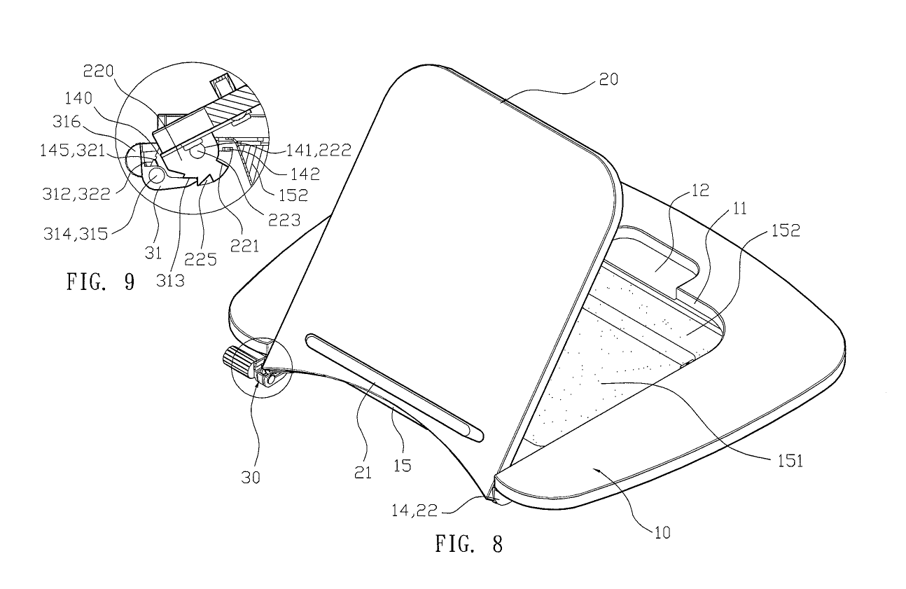

In operation, referring to FIGS. 6-11 with reference to FIGS. 1-5, when the movable board 20 is pivoted counterclockwise about the pivot pin 223 and is moved upward relative to the fixed board 10, the ratchet teeth 224 of the movable board 20 are rotated and moved to push the locking detent 313 of the limit member 31 downward so that the limit member 31 of the angle adjusting mechanism 3 is pivoted clockwise about the pivot shaft 315 and is moved downward relative to the movable board 20, and the locking detent 313 of the limit member 31 is moved downward to detach from the locking grooves 225 of the movable board 20. At this time, the elastic member 32 of the angle adjusting mechanism 3 is compressed to store a restoring force when the limit member 31 of the angle adjusting mechanism 3 is pivoted clockwise about the pivot shaft 315. In such a manner, the movable board 20 is moved upward relative to the fixed board 10 from the position as shown in FIGS. 6 and 7 to the position as shown in FIGS. 8 and 9 so as to adjust the inclined angle of the movable board 20 relative to the fixed board 10. Thus, when the support device is placed on a table, and an electronic equipment, such as a tablet PC, a notebook computer, a PDA, an electronic book and the like, is placed on the movable board 20, the electronic equipment is disposed at an inclined state to facilitate a user operating and watching the electronic equipment.

After adjustment of the inclined angle of the movable board 20 relative to the fixed board 10 is finished, the limit member 31 of the angle adjusting mechanism 3 is pivoted counterclockwise about the pivot shaft 315 by the restoring force of the elastic member 32 and is moved upward relative to the movable board 20, and the locking detent 313 of the limit member 31 is moved upward so that the locking detent 313 of the limit member 31 engages another one of the ratchet teeth 224 of the movable board 20 and is locked in another one of the locking grooves 225 of the movable board 20 as shown in FIG. 9 so as to lock the movable board 20 onto the fixed board 10 by the limit member 31 of the angle adjusting mechanism 3 as shown in FIG. 8.

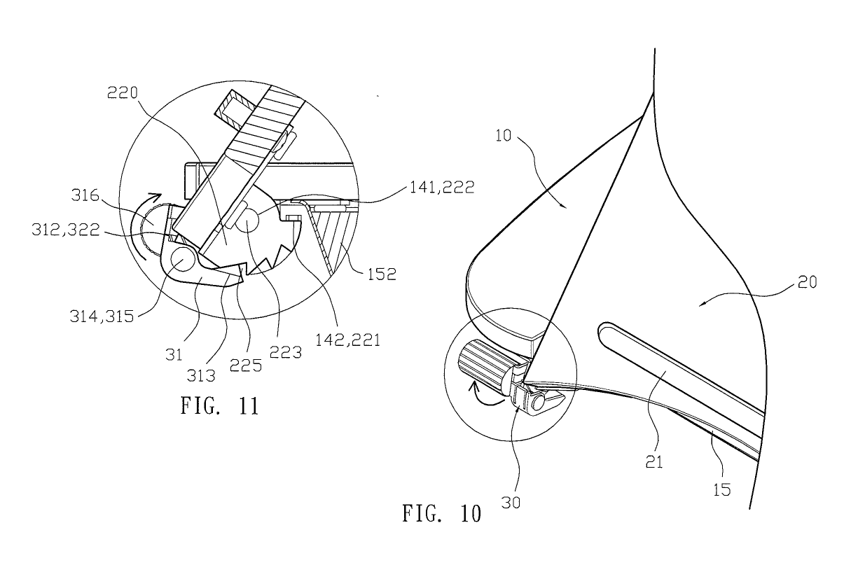

When the user wishes to fold the movable board 20, the limit member 31 of the angle adjusting mechanism 3 is pivoted clockwise about the pivot shaft 315 by rotation of the rotation knob 316 and is moved downward relative to the movable board 20, so that the locking detent 313 of the limit member 31 is moved downward to detach from the locking grooves 225 of the movable board 20 as shown in FIGS. 10 and 11 so as to release the movable board 20 from the limit member 31 of the angle adjusting mechanism 3. Thus, the movable board 20 is unlocked from the angle adjusting mechanism 3 and can be moved downward relative to the fixed board 10 from the position as shown in FIGS. 8 and 9 to the position as shown in FIGS. 6 and 7 so as to extend the movable board 20 into the opening 11 of the fixed board 10 and to fold the movable board 20 as shown in FIG. 1.

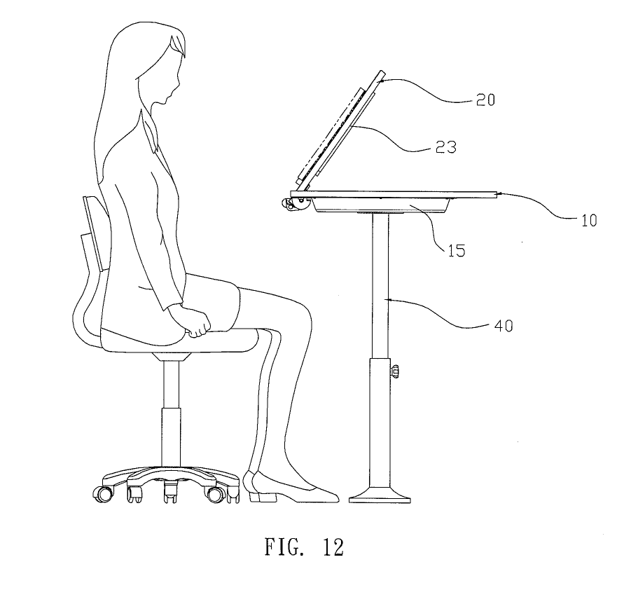

As shown in FIG. 12, the support device further comprises a retractable stand 40 mounted on a bottom of the receiving casing 15 to facilitate the user adjusting the height of the support device.

Accordingly, the movable board 20 is inclined relative to the fixed board 10 so that the electronic equipment placed on the movable board 20 is disposed at an inclined state to facilitate the user watching the electronic equipment and to provided a comfortable sensation to the user when operating the electronic equipment. In addition, the user only needs to pull and move the movable board 20 relative to the fixed board 10 so as to position the movable board 20 onto the fixed board 10 exactly so that the inclined angle of the movable board 20 relative to the fixed board 10 can be adjusted easily and quickly. Further, the movable board 20 is extended into the opening 11 of the fixed board 10 so that the support device can be folded to have a smaller volume when not in use to save the space and to facilitate storage and carrying of the support device.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A support device, comprising:
a fixed board;
a movable board pivotally connected with the fixed board; and
an angle adjusting mechanism mounted between the fixed board and the movable board to releasably lock the movable board onto the fixed board;
the fixed board has a side provided with two support seats;
the movable board has a side provided with two pivot seats pivotally connected with the two support seats of the fixed board respectively;
one of the two pivot seats of the movable board has a periphery provided with a plurality of oneway ratchet teeth;
the angle adjusting mechanism includes a limit member pivotally mounted on one of the two support seats of the fixed board and detachably engaging one of the two pivot seats of the movable board to releasably lock one of the two pivot seats of the movable board onto one of the two support seats of the fixed board and to releasably lock the movable board onto the fixed board;
the limit member of the angle adjusting mechanism has a first end pivotally connected with one of the two support seats of the fixed board and a second end provided with a locking detent detachably engaging one of the ratchet teeth of the movable board.

2. The support device of claim 1, wherein
the fixed board has a surface provided with an opening to receive the movable board;
the movable board is fully received in the opening of the fixed board;
one of the two support seats of the fixed board has a side provided with a fixing hole;
the first end of the limit member is pivotally connected with one of the two support seats of the fixed board by a pivot shaft;
the first end of the limit member has a side provided with a pivot hole aligning with the fixing hole of the fixed board;
the pivot shaft is extended through the pivot hole of the limit member and the fixing hole of the fixed board so that the limit member of the angle adjusting mechanism is pivotally connected with one of the two support seats of the fixed board.

3. The support device of claim 1, wherein
one of the two support seats of the fixed board has a periphery provided with an abutting edge;
the locking detent of the limit member is hooked onto the abutting edge of the fixed board.

4. The support device of claim 1, wherein
one of the two pivot seats of the movable board has a plurality of locking grooves defined between the ratchet teeth;
the locking detent of the limit member is detachably locked in one of the locking grooves of the movable board.

5. The support device of claim 2, wherein
the fixed board has a periphery provided with two stop blocks each extended into the opening of the fixed board to stop the movable board;
each of the two stop blocks of the fixed board has a side provided with an attractive member;
the movable board has an inner face provided with a buffering pad received in the opening of the fixed board;
the buffering pad of the movable board has a periphery provided with two attachment members each detachably attached to the attractive member of a respective one of the two stop blocks.

6. The support device of claim 2, wherein the support device further comprises:
a receiving casing mounted on the fixed board;
a buffering cushion mounted in the receiving casing and provided with a receiving chamber which is connected to the opening of the fixed board.

7. The support device of claim 2, wherein the opening 11 of the fixed board has a periphery provided with a finger slot connected to the movable board.

8. The support device of claim 5, wherein the movable board has an outer face provided with a transverse support bar.

9. The support device of claim 5, wherein the attractive member of each of the two stop blocks is a magnet or magnetic stone.

10. The support device of claim 1, wherein
each of the two support seats of the fixed board has a distal end provided with a protruding stop rib;
each of the two pivot seats of the movable board has a rim provided with a protruding limit lug that is movable to abut the stop rib of a respective one of the two support seats of the fixed board to stop a further movement of the movable board relative to the fixed board.

11. The support device of claim 2, wherein
the angle adjusting mechanism further includes an elastic member mounted in the limit member and biased between the limit member and one of the two support seats of the fixed board to force the locking detent of the limit member toward the ratchet teeth of the movable board;
one of the two support seats of the fixed board has a rim provided with a retaining recess;
the limit member of the angle adjusting mechanism has a side provided with a catch portion;
the elastic member of the angle adjusting mechanism has a first end provided with a hooked portion hooked in the retaining recess of the fixed board and a second end provided with a resting portion abutting the catch portion and the locking detent;
the elastic member of the angle adjusting mechanism is rotatably mounted on the pivot shaft.

12. The support device of claim 1, wherein the angle adjusting mechanism further includes a rotation knob secured on the limit member to drive and pivot the limit member relative to one of the two support seats of the fixed board and one of the two pivot seats of the movable board.

13. The support device of claim 11, wherein
the limit member of the angle adjusting mechanism has an inner portion provided with a receiving space to receive one of the two support seats of the fixed board and one of the two pivot seats of the movable board;
the receiving space of the limit member is located between the catch portion and the locking detent;
the pivot hole of the limit member is located between the catch portion and the locking detent;
the elastic member of the angle adjusting mechanism is received in the receiving space of the limit member.

14. The support device of claim 6, wherein the support device further comprises a retractable stand mounted on a bottom of the receiving casing.

15. The support device of claim 1, wherein
each of the two pivot seats of the movable board is pivotally connected with each of the two support seats of the fixed board by a pivot pin;
each of the two support seats of the fixed board has a mediate portion provided with a fixing bore;
each of the two pivot seats of the movable board has a central portion provided with a pivot bore;
the pivot pin is in turn extended through the pivot bore of each of the two pivot seats of the movable board and the fixing bore of each of the two support seats of the fixed board so that each of the two pivot seats of the movable board is pivotally connected with each of the two support seats of the fixed board;
the movable board is pivotable about the pivot pin and is movable relative to the fixed board.

16. The support device of claim 2, wherein
the ratchet teeth of the movable board are rotatable and movable relative to the fixed board and the angle adjusting mechanism by rotation of the movable board;
the limit member of the angle adjusting mechanism is pivotable about the pivot shaft and is movable relative to the movable board so that the locking detent of the limit member is movable relative to the ratchet teeth of the movable board.
